(19) United States
(12) Patent Application Publication
(10) Pub. No.: US 2024/0409812 A1
(43) Pub. Date: Dec. 12, 2024

(54) TREATMENT LIQUID

(71) Applicant: Tokyo Ohka Kogyo Co., Ltd., Kawasaki-shi (JP)

(72) Inventor: Takahiro Eto, Kawasaki-shi (JP)

(21) Appl. No.: 18/732,471

(22) Filed: Jun. 3, 2024

Related U.S. Application Data
(60) Provisional application No. 63/471,263, filed on Jun. 6, 2023.

(51) Int. Cl. C09K 13/06; C09K 13/08

(52) U.S. Cl. CPC C09K 13/06; C09K 13/08

(57) ABSTRACT

A treatment liquid containing a fluorine-containing compound, an organic solvent, a basic compound represented by General Formula NR¹R²R³, and water, in which a content of the organic solvent is 65% by mass or more with respect to a total amount of the treatment liquid, and a pH is 6 to 9. In the formula, R¹ to R³ are each independently a hydrogen atom or a hydrocarbon group which may have a substituent.

Priority is claimed on U.S. Provisional Application No. 63/471,263, filed on Jun. 6, 2023, the content of which is incorporated herein by reference.

### BACKGROUND OF THE INVENTION

### Field of the Invention

The present invention relates to a treatment liquid.

### Description of Related Art

In the wiring forming step, for example, a hard mask layer (HM layer) is formed on the interlayer insulating film on which a substrate, a metal wiring layer, and a silicon-based interlayer insulating film are laminated in this order, and the HM layer is etched to form a prototype of a wiring pattern. As the HM layer, a silicon-containing hard mask is generally used.

Next, the interlayer insulating film is dry etched using the etched HM layer as a mask to form the same wiring pattern as the mask. Next, the HM layer is removed, and for example, a copper metal film is embedded in the interlayer insulating film having the wiring pattern shape by electroplating.

An inorganic substance-containing residue derived from the metal wiring layer and a Si-containing residue derived from the HM layer are attached to the dry etched element (substrate/metal wiring layer/interlayer insulating film/HM layer).

In the related art, the dry etching residue is removed by a cleaning treatment. Various liquids have been proposed as the cleaning liquid for removing the dry etching residue.
Patent Document 1 proposes an etching liquid containing hydrofluoric acid, ammonium fluoride, and a salt of hydrogen fluoride and a base having a higher boiling point than ammonia.
Patent Document 2 proposes a cleaning liquid containing a carboxylic acid-type anionic surfactant: 0.001% to 5% by mass, a complexing agent: 0.005% to 5% by mass, a fluoride: 5% by mass or less, an alkali component: 30% by mass or less, and the balance of water and inevitable impurities.
Patent Document 3 proposes an aqueous cleaning composition containing at least one of oxidizing agent, at least one of oxidizing agent stabilizer including amines selected from the group consisting of a primary amine, a secondary amine, a tertiary amine, and an amine-N-oxide, and water.

### CITATION LIST

### Patent Documents

[Patent Document 1] PCT International Publication No. WO 2008/129944
[Patent Document 2] Japanese Unexamined Patent Application, First Publication No. 2005-194294
[Patent Document 3] Published Japanese Translation No. 2009-512194 of the PCT International Publication

### SUMMARY OF THE INVENTION

In the water-based treatment liquid containing a fluorine-containing compound such as hydrofluoric acid, which has been proposed in the related art, although the water-based treatment liquid is effective for removing a silicon-containing hard mask and etching residues on the silicon-containing hard mask, there are problems such as corrosion of a glass portion of a mask, and peeling or damage of a metal film such as a Ru film, which is used as a reflective film on a surface of the mask.

The present invention has been made in view of the above circumstances, and an object of the present invention is to provide a treatment liquid in which a silicon-containing hard mask and etching residues on a mask can be removed with good removability, and glass corrosion properties and metal corrosion properties are reduced.

In order to solve the above problem, the present invention has adopted the following configuration.
[1] A treatment liquid containing a fluorine-containing compound, an organic solvent, a basic compound represented by General Formula (1) described below, and water, in which a content of the organic solvent is 65% by mass or more with respect to a total amount of the treatment liquid, and a pH is 6 to 9.

NR¹R²R³ (1)
[In the formula, R¹ to R³ are each independently a hydrogen atom or a hydrocarbon group which may have a substituent.]
[2] The treatment liquid according to [1], in which a dipole moment of the organic solvent is 4 debye or less.
[3] The treatment liquid according to [1] or [2], in which the fluorine-containing compound contains hydrofluoric acid.
[4] The treatment liquid according to any one of [1] to [3], in which the treatment liquid is for producing a reflective film.

According to the present invention, it is possible to provide a treatment liquid which has good removability of the silicon-containing hard mask and etching residues on a mask and reduced the glass corrosion properties and the metal corrosion properties.

### BRIEF DESCRIPTION OF THE DRAWING

FIG. 1 is a cross-sectional view showing an example of an element after dry etching, which is a cleaning target.

### DETAILED DESCRIPTION OF THE INVENTION

### Treatment Liquid

The treatment liquid according to the present embodiment contains a fluorine-containing compound, an organic solvent, a basic compound represented by General Formula (1) described later, and water.

The treatment liquid according to the present embodiment is useful as a treatment liquid for removing a silicon-containing hard mask or etching residues containing an inorganic substance.

The term “inorganic substance” referred to herein is a compound including a metal atom, and examples thereof include a metal atom, a metal oxide, a metal nitride, a metal chloride, a metal fluoride, and the like. Examples of the metal atom include Ti, Ta, Cu, Co, Ru, Al, W, Mo, Au, Ag, Fe, Ni, Si, and the like. Examples of the metal oxide include TiOx, TaOx, CuOx, CoOx, RuOx, AlOx, WOx, MoOx, AuOx, AgOx, FeOx, NiOx, SiOx, and the like. Examples of the metal nitride include TiNx, TaNx, CuNx, CoNx, RuNx, AlNx, WNx, MoNx, AuNx, AgNx, FeNx, NiNx, SiNx, and the like. Examples of the metal chloride include TiClx, TaClx, CuClx, CoClx, RuClx, AlClx, WClx, MoClx, AuClx, AgClx, FeClx, NiClx, SiClx, and the like. Examples of the metal fluoride include TiFx, TaFx, CuFx, CoFx, RuFx, AlFx, WFx, MoFx, AuFx, AgFx, FeFx, NiFx, SiFx, and the like.

The etching residue is particularly a dry etching residue, and examples thereof include Si-containing residues derived from the HM layer and inorganic substance-containing residues derived from the metal wiring layer, which are attached in the wiring process. The dry etching residue needs to be removed before the next step because it deteriorates the yield and electrical properties of the semiconductor. The treatment liquid according to the present embodiment is suitable for cleaning a substrate after dry etching by a wiring process. The treatment liquid according to the present embodiment is particularly suitable for producing a reflective film.

Hereinafter, each component of the treatment liquid according to the present embodiment will be described.

### Fluorine-Containing Compound

The fluorine-containing compound has a function of removing (dissolving) a silicon-containing hard mask or etching residues containing an inorganic substance.

The fluorine-containing compound is not particularly limited as long as the compound contains a fluorine atom, and known fluorine-containing compounds can be used. Among these, as the fluorine-containing compound, a compound which dissociates and releases a fluoride ion in the treatment liquid is preferable.

Examples of the fluorine-containing compound include hydrofluoric acid (HF), ammonium fluoride, tetramethylammonium fluoride, hexafluorophosphoric acid, hexafluorosilicic acid, ammonium hexafluorophosphate, ammonium hexafluorosilicate, and the like.

In addition, as the counterion, a cation other than ammonium, for example, tetramethylammonium, and the like may be used.

From the viewpoint of further exhibiting the above-described function, the fluorine-containing compound is preferably hydrofluoric acid.

A content of the fluorine-containing compound is preferably 0.001% by mass or more, more preferably 0.01% by mass or more, and still more preferably 0.1% by mass or more with respect to the total amount of the treatment liquid. The upper limit value of the content of the fluorine-containing compound is not particularly limited, and is, for example, 5% by mass or less, and preferably 1% by mass or less during the use of the treatment liquid.

In a case where the content of the hydrofluoric acid is within the above-described preferred range, the removability of the silicon-containing hard mask or the etching residues containing an inorganic substance is likely to be improved.

### Organic Solvent

As the organic solvent, a water-soluble organic solvent is preferable.

Examples of the water-soluble organic solvent include an alcohol solvent, a glycol solvent, and a glycol ether solvent.

Examples of the alcohol solvent include methanol, ethanol, butanol, isobutanol, isoamyl alcohol, 3-methoxy-3-methyl-1-butanol, and the like.

Examples of the glycol solvent include ethylene glycol, propylene glycol, hexylene glycol, and the like.

Examples of the glycol ether solvent include methyl glycol, methyl diglycol, methyl triglycol, ethyl glycol, ethyl diglycol, ethyl triglycol, butyl glycol, butyl diglycol, butyl triglycol, propylene glycol monomethyl ether, dipropylene glycol monomethyl ether, and tripropylene glycol monomethyl ether.

The dipole moment of the organic solvent is preferably 4 debye or less, more preferably 3.6 debye or less, and still more preferably 3.3 debye or less.

The lower limit value of the dipole moment is not particularly limited, and is, for example, preferably 0 debye or more and more preferably 0.5 debye or more.

In a case where the dipole moment of the organic solvent is within the above-described preferred range, it is easy to inhibit the activity of the fluorine-containing compound, and it is easy to reduce the metal corrosion properties.

The organic solvent may be used alone or in combination of two or more types thereof.

Among these, as the organic solvent, at least one selected from the group consisting of 3-methoxy-3-methyl-1-butanol (MMB), methyl glycol (MG), methyl diglycol (MDG), methyl triglycol (MTG), butyl glycol (BG), butyl diglycol (BDG), butyl triglycol (BTG), ethylene glycol (EG), propylene glycol (PG), and propylene glycol monomethyl ether (PGME) is preferable, and 3-methoxy-3-methyl-1-butanol (MMB) is more preferable.

A content of the organic solvent is 65% by mass, is more preferably 75% by mass or more, and is still more preferably 85% by mass or more with respect to the total amount of the treatment liquid.

The upper limit value of the content of the organic solvent is not particularly limited, and is, for example, 99% by mass or less and preferably 95% by mass or less during the use of the treatment liquid.

In a case where the content of the organic solvent is 65% by mass or more, the glass corrosion properties and the metal corrosion properties are likely to be reduced.

### Basic Compound

The treatment liquid according to the present embodiment contains a basic compound represented by General Formula (1) described below.

NR¹R²R³ (1)

In the formula, R¹ to R³ are each independently a hydrogen atom or a hydrocarbon group which may have a substituent.

In the above-described Formula (1), the hydrocarbon group in R¹ to R³ may be linear, branched, or cyclic. The hydrocarbon group in R¹ to R³ may be a saturated hydrocarbon group or an unsaturated hydrocarbon group, but a saturated hydrocarbon group is preferable.

As the linear hydrocarbon group in R¹ to R³, a linear alkyl group having 1 to 15 carbon atoms is preferable, a linear alkyl group having 1 to 10 carbon atoms is more preferable, and a linear alkyl group having 1 to 6 carbon atoms is still more preferable.

As the branched hydrocarbon group in R¹ to R³, a branched alkyl group having 2 to 15 carbon atoms is preferable, a branched alkyl group having 2 to 10 carbon atoms is more preferable, and a branched alkyl group having 2 to 6 carbon atoms is still more preferable.

The cyclic hydrocarbon group in R¹ to R³ may be an alicyclic group or an aromatic hydrocarbon group. In addition, the cyclic hydrocarbon group in R¹ to R³ may be a polycyclic group or a monocyclic group.

Examples of the alicyclic group in R¹ to R³ include a cycloalkyl group having 3 to 20 carbon atoms.

Examples of the aromatic hydrocarbon group in R¹ to R³ include an aromatic hydrocarbon group having 5 to 20 carbon atoms.

The hydrocarbon group in R¹ to R³ may have a substituent. Examples of the substituent include a hydroxy group, an ether group (—O—), an amino group, and the like.

In the above-described Formula (1), R¹ to R³ are preferably a hydrogen atom, a linear or branched alkyl group, -L¹-OH,-L²-O-L³-OH, or -L⁴-NH². In the formulae, L¹ to L⁴ are each independently a linear or branched alkylene group.

As the linear alkylene group in L¹ to L⁴, a linear alkylene group having 1 to 15 carbon atoms is preferable, a linear alkylene group having 1 to 10 carbon atoms is more preferable, and a linear alkylene group having 1 to 6 carbon atoms is still more preferable.

As the branched alkylene group in L¹ to L⁴, a branched alkylene group having 2 to 15 carbon atoms is preferable, a branched alkylene group having 2 to 10 carbon atoms is more preferable, and a branched alkylene group having 2 to 6 carbon atoms is still more preferable.

One type of the basic compound may be used alone or two or more types thereof may be used in combination.

As the basic compound represented by the above-described Formula (1), at least one selected from the group consisting of monoisopropanolamine (MIPA), triethanolamine (TEA), monoethanolamine (MEA), diethanolamine (DEA), triethylamine, diethylenetriamine (DETA), diglycolamine (DGA), 2-amino-2-methyl-1-propanol (AMP), and ammonia (ammonium hydroxide: NH₄OH) is preferable, and monoisopropanolamine (MIPA) or monoethanolamine (MEA) is more preferable.

A content of the basic compound is preferably 0.01% to 10.0% by mass, more preferably 0.1% to 5.0% by mass, and still more preferably 0.1% to 1.0% by mass with respect to the total amount of the treatment liquid.

In a case where the content of the basic compound is within the above-described preferred range, the removability of the silicon-containing hard mask or the etching residue containing an inorganic substance and the reduction of the glass corrosion properties and the metal corrosion properties can be easily compatible.

### Anticorrosion Agent

The treatment liquid according to the present embodiment may contain an anticorrosion agent.

Examples of the anticorrosion agent include a compound containing a nitrogen-containing heterocyclic ring such as a triazole ring, an imidazole ring, a pyridine ring, a phenanthroline ring, a tetrazole ring, a pyrazole ring, a pyrimidine ring, a purine ring, and the like.

### Buffer

The treatment liquid according to the present embodiment may contain a buffer. The buffer is a compound having an action of inhibiting a change in pH of the treatment liquid.

The buffer is not particularly limited as long as it is a compound having a pH buffering ability. As the buffer, for example, a compound having a pKa of 6 to 11 can be used.

Examples of the buffer include Good buffers. Examples of the Good buffers include 2-cyclohexylaminoethanesulfonic acid (CHES), 3-cyclohexylaminopropanesulfonic acid (CAPS), N-tris(hydroxymethyl)methyl-3-aminopropanesulfonic acid (TAPS), 4-(cyclohexylamino)-1-butanesulfonic acid (CABS), tricine, bicine, 2-morpholinoethanesulfonic acid monohydrate (MES), bis(2-hydroxyethyl)aminotris(hydroxymethyl) methane (Bis-Tris), N-(2-acetamido)iminodiacetic acid (ADA), piperazine-1,4-bis(2-ethanesulfonic acid) (PIPES), N-(2-acetamido)-2-aminoethanesulfonic acid (ACES), 2-hydroxy-3-morpholinopropanesulfonic acid (MOPSO), N,N-bis(2-hydroxyethyl)-2-aminoethanesulfonic acid (BES), 3-morpholinopropanesulfonic acid (MOPS), N-tris(hydroxymethyl)methyl-2-aminoethanesulfonic acid (TES), 2-[4-(2-hydroxyethyl)-1-piperazinyl] ethanesulfonic acid (HEPES), 3-[N-tris(hydroxymethyl)methylamino]-2-hydroxypropanesulfonic acid (TAPSO), piperazine-1,4-bis(2-hydroxypropanesulfonic acid) (POPSO), 4-(2-hydroxyethyl) piperazine-1-(2-hydroxypropane-3-sulfonic acid) (HEPSO), 4-(2-hydroxyethyl)-1-piperazinepropanesulfonic acid (EPPS), and the like.

The treatment liquid of the present embodiment may not contain the buffer and may not contain one or more of the compounds exemplified as specific examples of the buffer.

### Surfactant

The treatment liquid according to the present embodiment may contain a surfactant for the purpose of adjusting the wettability of the treatment liquid to the substrate. Examples of the surfactant include a nonionic surfactant, an anionic surfactant, a cationic surfactant, and an amphoteric surfactant.

Examples of the nonionic surfactant include a polyalkylene oxide alkyl phenyl ether-based surfactant, a polyalkylene oxide alkyl ether-based surfactant, a block polymer-based surfactant consisting of polyethylene oxide and polypropylene oxide, a polyoxyalkylene distyrenated phenyl ether-based surfactant, a polyalkylene tribenzyl phenyl ether-based surfactant, an acetylene polyalkylene oxide-based surfactant, and the like.

Examples of the anionic surfactant include an alkylsulfonic acid, an alkylbenzenesulfonic acid, an alkylnaphthalenesulfonic acid, an alkyldiphenyl ether sulfonic acid, a fatty acid amidosulfonic acid, a polyoxyethylene alkyl ether carboxylic acid, a polyoxyethylene alkyl ether acetic acid, a polyoxyethylene alkyl ether propionic acid, an alkyl phosphonic acid, a fatty acid salt, and the like. Examples of the “salt” include an ammonium salt, a sodium salt, a potassium salt, a tetramethylammonium salt, and the like.

Examples of the cationic surfactant include an alkylpyridium-based surfactant, a quaternary ammonium salt-based surfactant, and the like.

Examples of the amphoteric surfactant include a betaine type surfactant, an amino acid type surfactant, an imidazoline type surfactant, an amine oxide type surfactant, and the like.

These surfactants are generally commercially available. One type of the surfactant may be used alone, or two or more types thereof may be used in combination.

In a case where the treatment liquid of the present embodiment contains the surfactant, the content of the surfactant is not particularly limited, but is, for example, preferably 0.0001% by mass to 5% by mass, more preferably 0.0002% by mass to 3% by mass, still more preferably 0.002% by mass to 1% by mass, and particularly preferably 0.002% by mass to 0.2% by mass with respect to the total mass of the treatment liquid.

The treatment liquid of the present embodiment may not contain one or more selected from the group consisting of a nonionic surfactant, an anionic surfactant, a cationic surfactant, and an amphoteric surfactant, and may not contain one or more of the compounds exemplified as the surfactant. The treatment liquid according to the present embodiment may not contain a surfactant.

### pH Adjusting Agent

The treatment liquid according to the present embodiment may contain a pH adjusting agent in order to adjust the pH to a desired pH. As the pH adjusting agent, an inorganic acid, an organic acid, an organic basic compound, or an inorganic basic compound can be appropriately used.

### Impurities and the Like

The treatment liquid of the present embodiment may include metal impurities including metal atoms such as an Fe atom, a Cr atom, a Ni atom, a Zn atom, a Ca atom, a Pb atom, and the like.

The total content of the metal atoms in the treatment liquid according to the present embodiment is preferably 100 ppt by mass or less with respect to the total mass of the treatment liquid. The lower limit value of the total content of the metal atoms is preferably as low as possible, and examples thereof include 0.001 ppt by mass or more. The total content of the metal atoms is, for example, 0.001 ppt by mass to 100 ppt by mass. In a case of setting the total content of the metal atoms to be equal to or smaller than the above mentioned preferred upper limit value, the defect inhibitory properties and the residue inhibitory properties of the treatment liquid are improved. It is considered that in a case of setting the total content of the metal atoms to be equal to or more than the abovementioned preferred lower limit value, the metal atoms are released and less likely to be present in the system, resulting in a less negative impact on a production yield of the entire object to be cleaned.

The content of the metal impurities can be adjusted by, for example, a purification treatment such as filtering. The purification treatment such as filtering may be partially or entirely performed on the raw materials before preparing the treatment liquid, or may be performed after preparing the treatment liquid.

The treatment liquid of the present embodiment may include, for example, impurities derived from organic substances (organic impurities). The total content of the organic impurities in the treatment liquid of the present embodiment is preferably 5,000 ppm by mass or less. The lower limit of the content of the organic impurities is preferably as low as possible, and the lower limit is, for example, equal to or more than 0.1 ppm by mass. The total content of the organic impurities is, for example, 0.1 ppm by mass to 5,000 ppm by mass.

The treatment liquid of the present embodiment may include, for example, objects to be counted having a size to be countable using a light scattering liquid particle counter. The size of the object to be counted is, for example, 0.04 μm or more. The number of the objects to be counted in the treatment liquid according to the present embodiment is, for example, 1,000 or less per 1 mL of the treatment liquid, and the lower limit value thereof is, for example, 1 or more. It is considered that the effect of inhibiting the metal corrosion by the treatment liquid is improved by setting the number of the objects to be counted in the treatment liquid to the above-described range.

The organic impurities and/or the objects to be counted may be added to the treatment liquid or may be unavoidably mixed in the treatment liquid in a production step of the treatment liquid. Examples of the cases where the organic impurities are unavoidably mixed in the production step of the treatment liquid include a case where the organic impurities are included in raw materials (for example, organic solvents) used in the production of the treatment liquid, a case where the organic impurities are mixed in from the external environment during the production step of the treatment liquid (for example, contamination), and the like, but the cases are not limited to the above.

In a case of the objects to be counted are added to the treatment liquid, the abundance ratio may be adjusted for each specific size, taking into consideration the surface roughness, and the like of the object to be cleaned.

### pH of Treatment Liquid

A pH of the treatment liquid according to the present embodiment is 6 to 9 as measured at 23° C., preferably 6.5 to 9.0, and more preferably 7.0 to 9.0.

In a case where the pH of the treatment liquid is in the range of 6 to 9, the removability of the silicon-containing hard mask or the etching residues containing an inorganic substance is likely to be improved.

The pH of the treatment liquid is a value measured by a pH meter at 23° C. under a condition of normal pressure (1 atmosphere).

With the treatment liquid according to the present embodiment described above, the silicon-containing hard mask or the dry etching residues can be easily removed, and the glass corrosion properties and the metal corrosion properties are reduced. The treatment liquid according to the present embodiment contains hydrofluoric acid and the organic solvent in an amount of 65% by mass or more with respect to the total amount of the treatment liquid. Accordingly, it is presumed that the corrosion of glass or metal by hydrofluoric acid can be reduced. Further, the treatment liquid according to the present embodiment further contains the basic compound represented by Formula (1), and has a pH of 6 to 9. Therefore, it is presumed that the corrosion of glass or metal can be reduced while inhibiting deterioration of the removability of the silicon-containing hard mask or the dry etching residues by the organic solvent.

### Method of Treating Substrate

The method of treating a substrate according to the present embodiment includes a step (P1) of treating a substrate including a silicon-containing hard mask with the treatment liquid.

In the treatment method according to the present embodiment, the substrate to be cleaned includes a single substrate and an element including the substrate. The step (P1) includes removal of etching residues on the substrate and removal of the silicon-containing hard mask.

The element may be, for example, an element obtained after performing dry etching of the metal wiring layer by a semi-damascene process. Further, the element may be an element in which a metal wiring layer is exposed after a Si-containing layer (for example, a Si-containing interlayer insulating film) is dry etched in the wiring process. Also, the element may be a substrate in which the metal wiring layer is exposed after a CMP step in the wiring process.

The metal wiring layer is preferably a layer containing at least one metal selected from the group consisting of molybdenum, tungsten, ruthenium, copper, iron, nickel, aluminum, lead, zinc, tin, tantalum, magnesium, cobalt, bismuth, cadmium, titanium, zirconium, antimony, manganese, beryllium, chromium, germanium, vanadium, gallium, hafnium, indium, niobium, rhenium, and thallium.

Hereinafter, an embodiment of a method of treating a substrate according to the present aspect will be described with reference to the drawings.

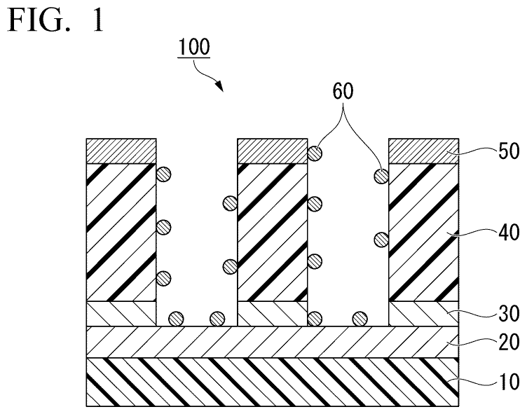

FIG. 1 shows an example of an element (substrate/metal wiring layer/interlayer insulating film/HM layer) after dry etching, which is a treatment target.

In the element 100 shown in FIG. 1, a substrate 10, a metal wiring layer 20, an etching stop layer 30, and an interlayer insulating film 40 are laminated in this order, and a hard mask layer (HM layer) 50 is formed on the interlayer insulating film 40.

The element 100 is the one after dry etching is performed by a wiring process, that is, the one in a state after the interlayer insulating film 40 is dry etched using the HM layer 50 in which the prototype of the wiring pattern is formed by the dry etching as a mask. Dry etching residues 60 are attached to the side surfaces of the HM layer 50 and the interlayer insulating film 40.

The metal wiring layer 20 is exposed in a space portion between the interlayer insulating films 40 having the wiring pattern shape, and the dry etching residues 60 are also attached to the space portion.

The substrate 10 consists of a material such as silicon, amorphous silicon, glass, and the like.

The metal wiring layer 20 is a wiring layer consisting of a metal such as molybdenum, tungsten, ruthenium, copper, iron, nickel, aluminum, lead, zinc, tin, tantalum, magnesium, cobalt, bismuth, cadmium, titanium, zirconium, antimony, manganese, beryllium, chromium, germanium, vanadium, gallium, hafnium, indium, niobium, rhenium, thallium, and the like.

The interlayer insulating film 40 consists of a silicon-based material such as SiO₂, SiN, SiOC, and the like.

The HM layer 50 consists of a silicon-based material.

The dry etching residues 60 are mainly Si-containing residues containing a silicon-based material derived from the HM layer 50.

### Treatment Step (P1)

The present step (P1) is a step of treating the element 100 after dry etching is performed by the wiring process using the treatment liquid according to the first aspect.

The above-described treatment includes removal of etching residues, impurities, and the like, and removal of the HM layer 50 on the element 100.

The treatment method is not particularly limited, and a known treatment method can be used.

When the element 100 to be treated is brought into contact with the treatment liquid, the treatment liquid may be diluted 2 to 2000 times to obtain a diluted liquid, and then the treatment operation may be executed using this diluted liquid.

Examples of the treatment operation include a method in which the treatment liquid is continuously applied onto the element 100 rotating at a constant rate (a spin coating method), a method in which the element 100 is immersed in the treatment liquid for a certain period of time (a dipping method), a method in which the treatment liquid is sprayed onto the surface of the element 100 (a spraying method), and the like.

A temperature at which the treatment is performed is not particularly limited. The treatment is preferably performed under the conditions of 10° C. to 80° C., and may be performed at 20° C. to 75° C. or 40° C. to 70° C.

By increasing the temperature of the treatment liquid, the removability of the etching residues or the silicon-containing hard mask are improved, but in consideration of reducing the change in composition of the treatment liquid to the minimum, workability, safety, cost, and the like, the temperature of the treatment liquid can be appropriately selected.

For the treatment time, a time sufficient to remove the etching residues, impurities, or the silicon-containing hard mask attached to the surface of the element 100 can be appropriately selected. The treatment time is, for example, 10 seconds to 30 minutes, and may be 20 seconds to 15 minutes, 30 seconds to 10 minutes, or 30 seconds to 5 minutes.

According to the treatment method according to the present embodiment described above, since the treatment liquid is used, in the element 100 to which the dry etching residues 60 are attached, the dry etching residues 60 derived from the HM layer 50 and/or the HM layer 50 can be satisfactorily removed while inhibiting the damage to the metal wiring layer 20. In addition, according to the treatment method of the present embodiment, the damage to the interlayer insulating film 40 is also inhibited.

### Method for Producing Semiconductor Element

A method for producing a semiconductor element according to the present embodiment includes a step (P1) of treating a substrate provided with a silicon-containing hard mask using the treatment liquid.

As an embodiment of the method for producing a semiconductor element, a production method including the step (P1) and optional steps is an exemplary example.

In the production method according to the present embodiment, the step (P1) can be carried out in the same manner as the method described in [treatment step (P1)] in (the method of treating a substrate) described above.

Examples of the optional steps include a hard mask layer etching step, a wiring layer dry etching step, a contact etching step, and the like before the step (P1). Furthermore, examples of the optional steps include known steps performed when producing a semiconductor element, for example, steps of forming a capacitor, forming a channel, forming a high-K/metal gate, and forming each structure such as a metal wiring, a gate structure, a source structure, a drain structure, an insulating layer, a ferromagnetic layer, and a non-magnetic layer (layer formation, etching other than the above-described etching treatment, chemical mechanical polishing, transformation, and the like), a resist film formation step, an exposure step, a development step, a heat treatment step, an inspection step, and the like.

In the embodiment, the exposure step includes irradiating the resist film with extreme ultraviolet rays (EUV).

According to the method for producing a semiconductor element of the present embodiment as explained above, since the step (P1) of cleaning the substrate provided with the silicon-containing hard mask using the treatment liquid is included, it is possible to remove the etching residues and/or the silicon-containing hard mask satisfactorily while inhibiting the damage to the metal wiring. As a result, electrical properties of the produced semiconductor element are improved.

### Examples

Hereinafter, the present invention will be described in more detail with reference to Examples, but the present invention is not limited to these examples.

### Dipole Moment of Organic Solvent

The dipole moment of the organic solvent used in each example was calculated by CAChe Work System Pro Version 6.1.12.33.

### pH of Treatment Liquid

For the semiconductor treatment liquid of each example, the pH at 23° C. was measured using a pH meter.

The components used in Examples and Comparative Examples are shown below.

Each component shown in Tables 1 and 2 was mixed to prepare a treatment liquid of each example.

TABLE 1

| | Fluorine-containing | Organic | Dipole | Basic | | |
|---|---|---|---|---|---|---|
| | compound | solvent | moment | compound | Water | pH |
| Example 1 | HF | MMB | 3.234 | MIPA | Residues | 7.5 |
| | [0.3] | [90] | | [0.50] | | |
| Example 2 | HF | MG | 0.374 | MIPA | Residues | 6.7 |
| | [0.3] | [90] | | [0.50] | | |
| Example 3 | HF | MDG | 1.718 | MIPA | Residues | 7.0 |
| | [0.3] | [90] | | [0.50] | | |
| Example 4 | HF | MTG | 0.391 | MIPA | Residues | 7.2 |
| | [0.3] | [90] | | [0.50] | | |
| Example 5 | HF | BG | 0.704 | MIPA | Residues | 6.3 |
| | [0.3] | [90] | | [0.50] | | |
| Example 6 | HF | BDG | 1.732 | MIPA | Residues | 6.5 |
| | [0.3] | [90] | | [0.50] | | |
| Example 7 | HF | BTG | 0.681 | MIPA | Residues | 6.7 |
| | [0.3] | [90] | | [0.50] | | |
| Example 8 | HF | EG | 0.001 | MIPA | Residues | 6.5 |
| | [0.3] | [90] | | [0.50] | | |
| Example 9 | HF | PG | 0.312 | MIPA | Residues | 6.7 |
| | [0.3] | [90] | | [0.50] | | |
| Example 10 | HF | PGME | 1.811 | MIPA | Residues | 6.9 |
| | [0.3] | [90] | | [0.50] | | |
| Example 11 | HF | MMB | 3.234 | MIPA | Residues | 7.0 |
| | [0.3] | [80] | | [0.50] | | |
| Example 12 | HF | BDG | 1.718 | MIPA | Residues | 6.0 |
| | [0.3] | [80] | | [0.50] | | |
| Example 13 | HF | MMB | 3.234 | MIPA | Residues | 6.7 |
| | [0.3] | [70] | | [0.50] | | |
| Example 14 | HF | BDG | 1.718 | MIPA | Residues | 6.0 |
| | [0.3] | [70] | | [0.50] | | |
| Example 15 | HF | MMB | 3.234 | TEA | Residues | 7.2 |
| | [0.3] | [90] | | [1.00] | | |
| Example 16 | HF | MMB | 3.234 | MEA | Residues | 7.7 |
| | [0.3] | [90] | | [0.50] | | |
| Example 17 | HF | MMB | 3.234 | DEA | Residues | 6.3 |
| | [0.3] | [90] | | [0.50] | | |
| Example 18 | HF | MMB | 3.234 | Triethylamine | Residues | 6.7 |
| | [0.3] | [90] | | [0.50] | | |
| Example 19 | HF | MMB | 3.234 | DETA | Residues | 7.5 |
| | [0.3] | [90] | | [0.50] | | |
| Example 20 | HF | MMB | 3.234 | DGA | Residues | 6.3 |
| | [0.3] | [90] | | [0.50] | | |
| Example 21 | HF | MMB | 3.234 | AMP | Residues | 7.2 |
| | [0.3] | [90] | | [0.50] | | |
| Example 22 | HF | MMB | 3.234 | NH4OH | Residues | 7.7 |
| | [0.3] | [90] | | [0.10] | | |

TABLE 2

| | Fluorine-containing | Organic | Dipole | Basic | | |
|---|---|---|---|---|---|---|
| | compound | solvent | moment | compound | Water | pH |
| Comparative | HF | — | | — | Residues | 3.0 |
| Example 1 | [0.3] | | | | | |
| Comparative | HF | MMB | 3.234 | — | Residues | 3.5 |
| Example 2 | [0.3] | [90] | | | | |
| Comparative | HF | MMB | 3.234 | MIPA | Residues | 10.0 |
| Example 3 | [0.3] | [90] | | [5.00] | | |
| Comparative | HF | — | | MIPA | Residues | 4.5 |
| Example 4 | [0.3] | | | [0.50] | | |
| Comparative | HF | MMB | 3.234 | MIPA | Residues | 5.0 |
| Example 5 | [0.3] | [30] | | [0.50] | | |
| Comparative | HF | MMB | 3.234 | MIPA | Residues | 6.0 |
| Example 6 | [0.3] | [60] | | [0.50] | | |
| Comparative | HF | DMSO | 4.602 | MIPA | Residues | 7.1 |
| Example 7 | [0.3] | [90] | | [0.30] | | |
| Comparative | HF | Sulfolane | 5.401 | MIPA | Residues | 7.2 |
| Example 8 | [0.3] | [90] | | [0.30] | | |
| Comparative | HF | NMP | 4.616 | MIPA | Residues | 7.0 |
| Example 9 | [0.3] | [90] | | [0.05] | | |
| Comparative | HF | NEP | 4.667 | MIPA | Residues | 7.0 |
| Example 10 | [0.3] | [90] | | [0.05] | | |
| Comparative | HF | DMI | 4.543 | MIPA | Residues | 7.1 |
| Example 11 | [0.3] | [90] | | [0.10] | | |
| Comparative | HF | DMF | 4.532 | MIPA | Residues | 6.9 |
| Example 12 | [0.3] | [90] | | [0.10] | | |
| Comparative | HF | DEF | 4.749 | MIPA | Residues | 6.9 |
| Example 13 | [0.3] | [90] | | [0.10] | | |

In Tables 1 and 2, each abbreviation has the following meaning. The value in [ ] is the blending amount (% by mass).
HF: hydrofluoric acid
MMB: 3-methoxy-3-methyl-1-butanol
MG: methyl glycol
MDG: methyl diglycol
MTG: methyl triglycol
BG: butyl glycol
BDG: butyl diglycol
BTG: butyl triglycol
EG: ethylene glycol
PG: propylene glycol
PGME: propylene glycol monomethyl ether
MIPA: monoisopropanolamine
TEA: triethanolamine
MEA: monoethanolamine
DEA: diethanolamine
Triethylamine: triethylamine
DETA: diethylenetriamine
DGA: diglycolamine
AMP: 2-amino-2-methyl-1-propanol
NH₄OH: ammonium hydroxide
DMSO: dimethylsulfoxide
Sulfolane: sulfolane
NMP: N-methyl-2-pyrrolidone
NEP: N-ethyl-2-pyrrolidone
DMI: 1,3-dimethyl-2-imidazolidinone
DMF: N,N-dimethylformamide
DEF: N,N-diethylformamide

### Removability of Hard Mask

The wafer provided with the silicon-containing hard mask was dipped in the treatment liquid set at 25° C. for 3 minutes, and the silicon-containing hard mask was observed using an SEM photograph and evaluated according to the following evaluation criteria. The results are shown in Tables 3 and 4 as “HM removability”.

Evaluation criteria
A: 100% removed
B: 90% to 99% removed
C: less than 90% removed

### Glass Corrosion Properties (Dipping Method)

A glass plate was dipped in the treatment liquid at 25° C. for 10 minutes, and the metal was observed using an SEM photograph and evaluated according to the following evaluation criteria. The results are shown in Tables 3 and 4 as “Glass damage”.

### Evaluation Criteria

A: 0% damaged
B: 1% to 9% damaged
C: 10% or more damaged

### Metal Corrosion Properties (Dipping Method)

The wafer on which the metal had been formed was dipped in the treatment liquid at 25° C. for 10 minutes, and the metal was observed using an SEM photograph and evaluated according to the following evaluation criteria. The results are shown in Tables 3 and 4 as “Ru damage”.

### Evaluation Criteria

A: 0% damaged
B: 1% to 9% damaged
C: 10% or more damaged

TABLE 3

| | HM | Glass | Ru |
|---|---|---|---|
| | Removability | damage | damage |
| Example 1 | A | A | A |
| Example 2 | A | A | A |
| Example 3 | A | A | A |
| Example 4 | A | A | A |
| Example 5 | A | A | A |
| Example 6 | A | A | A |
| Example 7 | A | A | A |
| Example 8 | A | A | A |
| Example 9 | A | A | A |
| Example 10 | A | A | A |
| Example 11 | A | A | A |
| Example 12 | A | A | A |
| Example 13 | A | A | A |
| Example 14 | A | A | A |
| Example 15 | A | A | A |
| Example 16 | A | A | A |
| Example 17 | A | A | A |
| Example 18 | A | A | A |
| Example 19 | A | A | A |
| Example 20 | A | A | A |
| Example 21 | A | A | A |
| Example 22 | A | A | A |

TABLE 4

| | HM | Glass | Ru |
|---|---|---|---|
| | Removability | damage | damage |
| Comparative | A | C | C |
| Example 1 | | | |
| Comparative | C | A | A |
| Example 2 | | | |
| Comparative | C | A | A |
| Example 3 | | | |
| Comparative | A | C | C |
| Example 4 | | | |
| Comparative | A | C | C |
| Example 5 | | | |
| Comparative | A | B | B |
| Example 6 | | | |
| Comparative | A | C | C |
| Example 7 | | | |
| Comparative | A | C | C |
| Example 8 | | | |
| Comparative | A | C | C |
| Example 9 | | | |
| Comparative | A | C | C |
| Example 10 | | | |
| Comparative | A | C | C |
| Example 11 | | | |
| Comparative | A | C | C |
| Example 12 | | | |
| Comparative | A | C | C |
| Example 13 | | | |

From the results shown in Tables 3 and 4, it was confirmed that the treatment liquids of Examples 1 to 22 had satisfactory removability of the silicon-containing hard mask, and the glass corrosion properties and the metal corrosion properties were reduced.

While preferred embodiments of the invention have been described and illustrated above, it should be understood that these are exemplary of the invention and are not to be considered as limiting. Additions, omissions, substitutions, and other modifications can be made without departing from the scope of the invention. Accordingly, the invention is not to be considered as being limited by the foregoing description and is only limited by the scope of the appended claims.

What is claimed is:

1. A treatment liquid comprising:
a fluorine-containing compound;
an organic solvent;
a basic compound represented by General Formula (1) described below; and water,
wherein a content of the organic solvent is 65% by mass or more with respect to a total amount of the treatment liquid, and
a pH is 6 to 9,
NR¹R²R³ (1)
wherein R¹ to R³ are each independently a hydrogen atom or a hydrocarbon group which may have a substituent.

2. The treatment liquid according to claim 1, wherein a dipole moment of the organic solvent is 4 debye or less.

3. The treatment liquid according to claim 1, wherein the fluorine-containing compound contains hydrofluoric acid.

4. The treatment liquid according to claim 1, wherein the treatment liquid is for producing a reflective film.
